(19) United States
(12) Patent Application Publication
(10) Pub. No.: US 2026/0029494 A1
(43) Pub. Date: Jan. 29, 2026

(54) Filter Unit for a Cable Unit Having a Cooling Unit

(71) Applicant: Siemens Healthineers AG, Forchheim (DE)

(72) Inventors: Thomas Beck, Dormitz (DE); Stephan Biber, Erlangen (DE)

(73) Assignee: Siemens Healthineers AG, Forchheim (DE)

(21) Appl. No.: 19/279,084

(22) Filed: Jul. 24, 2025

(30) Foreign Application Priority Data
Jul. 25, 2024 (DE) 10 2024 207 017.3

(51) Int. Cl. G01R 33/34; G01R 33/36

(52) U.S. Cl. CPC G01R 33/3403; G01R 33/3607

(57) ABSTRACT

The disclosure relates to a filter unit for a cable unit connecting a gradient coil unit to a gradient controller. The filter unit may include a filter and a cooler. The cooler may include a cooling line through which a cooling medium can flow. The cooler may be configured to cool the filter.

### CROSS REFERENCE TO RELATED APPLICATIONS

This patent application claims priority to German Patent Application No. 10 2024 207 017.3, filed Jul. 25, 2024, which is incorporated herein by reference in its entirety.

### BACKGROUND

### Field

The disclosure relates to a filter unit for a cable unit connecting a gradient coil unit to a gradient controller comprising a filter and a cooling unit, and to a system comprising said filter unit.

### Related Art

Magnetic resonance imaging is based on alternating electromagnetic fields (RF fields) generated by a magnetic resonance device and their interaction with a static magnetic field of usually 1.5 tesla or 3 tesla. To prevent impairment of its functionality, the magnetic resonance device is usually located in a separate, RF-shielded room, which may be enclosed by an RF shield, configured to shield the generated fields from external influences and prevents the electromagnetic fields generated by the magnetic resonance device from propagating outside the RF-shielded room. Components situated in the RF-shielded room are subject to particular requirements so that their operation is not impaired by the operation of the magnetic resonance device, and their operation does not impair the operation of the magnetic resonance device. The RF shield is designed in particular to shield RF fields at frequencies in the region of the Larmor frequency of the hydrogen protons, in particular RF fields at frequencies of at least 1 MHz. In an exemplary embodiment, all the RF fields are shielded for improved magnetic resonance imaging.

The control of the magnetic resonance device and in particular the control of the gradient coil unit required for the spatial encoding in magnetic resonance imaging is typically performed using a controller and by means of power amplifiers, which are typically located outside the RF-shielded room. In particular, the power amplifiers connected to the gradient coil unit generate electrical currents of up to 1200 A at frequencies in the range between 100 Hz and 10 kHz. These electrical currents are supplied to the gradient coil unit by means of an electrical conductor, in particular a cable unit, and therefore an electrical connection between the gradient coil unit and the power amplifier is required through the RF shield. In order to maintain the shielding action of the RF shield, filtering of the electrical conductor, i.e. of the cable unit, is necessary, without said filter simultaneously impairing the functionality of the electrical conductor between the gradient coil unit and the power amplifier.

The efficiency of a filter can be measured on the basis of a power that the filter can transfer to the gradient coil unit. The power can be increased, for example, by using coils containing low-resistance and/or large-diameter wires and/or large coils. The power of a filter can also be increased by efficient dissipation of heat produced during operation of the filter. It is conventional to cool the filter by means of circulating air, potentially assisted by fans which generate an air flow around the filter but which have a high noise level and high wear.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic representation of an exemplary embodiment of a filter unit according to the disclosure.

FIG. 2 shows a schematic representation of an exemplary embodiment of a filter unit according to the disclosure.

FIG. 3 shows a schematic representation of an exemplary embodiment of a filter unit according to the disclosure.

FIG. 4 shows a schematic representation of an exemplary embodiment of a filter unit according to the disclosure.

FIG. 5 shows a schematic representation of an exemplary embodiment of a filter unit according to the disclosure.

FIG. 6 shows a schematic representation of an exemplary embodiment of a filter unit according to the disclosure.

FIG. 7 shows a schematic representation of an exemplary embodiment of a filter unit according to the disclosure.

FIG. 8 shows a schematic representation of a system according to the disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to define a particularly powerful and robust filter unit that has a filter for a cable unit. The filter unit according to the disclosure for a cable unit, which cable unit connects a gradient coil unit to a gradient controller, may comprise a filter and a cooling unit. The cooling unit may comprise a cooling line, through which a cooling medium can flow, and the cooling unit is configured to cool, in particular actively cool, the filter. The filter unit may comprise a receptacle and/or connection unit for the cable unit. The filter unit can comprise the cable unit. The cable unit typically may comprise an electrical conductor. The gradient controller typically corresponds to an energy source. The gradient coil unit typically corresponds to a consumer.

The filter is typically a low-pass filter and/or a bandpass filter. For example, the filter can be in the form of a coil and/or comprise an LC resonant circuit. The frequencies passed by the filter typically equal less than 20 kHz, preferably less than 10 kHz, particularly preferably less than 5 kHz. The frequencies blocked by the filter typically equal more than 1 MHz, which can typically influence the receive electronics.

The cooling medium typically may comprise a liquid and/or a fluid and/or a gas. The cooling unit can comprise the cooling medium. The cooling line is typically closed in such a way that the cooling medium can perform a directional flow through the cooling line. For this purpose, the cooling unit can comprise a pump for producing a flow and/or stream of the cooling medium, in particular through the cooling line. The cooling unit can be part of a cooling circuit and/or comprise a cooling circuit. The cooling circuit typically may comprise a pump and/or a cooling reservoir, wherein the pump is configured to conduct the cooling medium from the cooling reservoir through the cooling line to the filter. The cooling circuit typically also may comprise a unit configured to actively lower the temperature of the cooling medium.

The temperature of the filter unit according to the disclosure can be controlled particularly well and precisely, whereby the filter unit is particularly powerful and robust. This allows efficient conduction of high currents and/or high electrical power through the filter, whereby the combination of gradient controller, gradient coil unit and the connecting cable unit can be operated particularly efficiently with good shielding by the filter, ensuring interference-free operation of the gradient coil unit and the magnetic resonance device.

An embodiment of the filter unit provides that the cable unit may comprise at least three cable elements, and the filter unit may comprise at least three filters, wherein each filter of the at least three filters is assigned to one cable element of the at least three cable elements, and the cooling line is configured such that at least two filters of the at least three filters are cooled in series.

The gradient coil unit typically may comprise three gradient coils, which are configured to generate magnetic field gradients in three mutually different and typically mutually orthogonal spatial directions. Each gradient coil is controlled here separately in accordance with an MR control sequence, and therefore a cable element typically connects a gradient coil to the gradient controller. The gradient controller can comprise three power amplifiers, in particular three gradient amplifiers and/or three amplifier units, and therefore each gradient coil is connected to an amplifier unit via a cable element. A cable element is typically an electrical conductor. This embodiment provides a filter for each of the three cable elements, allowing each cable element to be filtered separately on passing through the RF shield.

The cooling unit may be configured such that the cooling line is in contact with and/or passes through at least two filters in succession. The cooling unit may be configured such that the at least two filters can be cooled in series by the cooling line. This allows a particularly compact construction and efficient cooling of the filters.

An embodiment of the filter unit provides that at least part of the cooling line has at least two sub-cooling lines, which are parallel to each other. According to this embodiment, the cooling line is subdivided in at least one segment into at least two sub-cooling lines. This segment of the cooling line typically runs through the RF shield and/or is located at the at least one filter. The at least two sub-cooling lines can be joined before and after the at least one filter. The parallel interconnection according to this embodiment allows branched distribution of the cooling medium and increases the surface area of the cooling line in the region of the filter. This increases the cooling capacity and hence the efficiency of the filter unit.

An embodiment of the filter unit provides that the cable unit may comprise at least three cable elements, and the filter unit may comprise at least three filters, wherein each filter of the at least three filters is assigned to one cable element of the at least three cable elements, and the at least two sub-cooling lines are configured such that at least two filters of the at least three filters are each assigned a sub-cooling line and/or are each cooled by a sub-cooling line.

The cooling line may comprise, at least in segments, three sub-cooling lines connected in parallel. The parallel-connected sub-cooling lines can be joined before and after the segment. The assignment of at least one sub-cooling line to one filter each allows particularly good cooling of all three filters. This increases the cooling capacity and hence the efficiency of the filter unit.

An exemplary embodiment of the filter unit provides that the cooling unit is independent of an overall cooling unit for cooling of components of a magnetic resonance device and/or of the gradient coil unit.

The cooling line may be accordingly part of a filter cooling circuit, i.e. part of a cooling circuit that is additional to the overall cooling unit. This allows individual control of the velocity and/or temperature of the cooling medium and/or individual selection of the cooling medium itself, whereby the filter can be cooled individually in particular.

An exemplary embodiment of the filter unit provides that the cooling unit may comprise a cooling element, and the cooling medium influences the temperature of the cooling element. The cooling element can comprise a plate cooler. The cooling medium can typically influence and/or indirectly regulate the temperature of the cooling element. The filter is typically in physical contact with the cooling element. This allows temperature regulation of the filter without the filter having direct contact with the cooling medium. Such a cooling unit is particularly robust.

An exemplary embodiment of the filter unit provides that the filter is integrated in the cooling line. The cooling line can enclose the filter in such a way that the cooling medium can flow through at least part of the filter. The filter can also comprise connections to which the cooling line can be connected in a reversibly detachable manner. This allows particularly good cooling.

An exemplary embodiment of the filter unit provides that the cooling unit is free of air-cooling and/or free of a fan. The filter unit according to the disclosure can dispense with fans and can hence have a particularly quiet design. Moreover, fans are prone to wear. Dispensing with them allows a particularly robust filter unit.

An exemplary embodiment of the filter unit provides that the filter unit may comprise a housing unit, and an exterior of the housing unit has a maximum temperature of 55° C. during operation of the filter unit. The housing unit may enclose the filter and the cable unit, such as in a way that the housing unit shields them from the surroundings. This can ensure, for example, that a raised temperature inside the housing unit has no negative effects on the surroundings.

The disclosure is also based on a system comprising a gradient coil unit of a magnetic resonance device, a gradient controller, an RF-shielded room enclosed by an RF shield, and a filter unit according to the disclosure for a cable unit, wherein the gradient coil unit is located inside the RF-shielded room and the gradient controller is located outside the RF-shielded room, the cable unit connects the gradient coil unit to the gradient controller, and the filter unit is integrated in the RF shield. The system may comprise a cooling unit, wherein the cooling unit may comprise a cooling line through which a cooling medium can flow, and the cooling unit is configured to cool the filter. The system can comprise the magnetic resonance device and/or the RF shield and/or the RF-shielded room.

The advantages of the system are essentially the same as the advantages of the filter according to the disclosure, which are presented in detail above. Features, advantages or alternative embodiments of the filter mentioned in this connection and also the alternative embodiments of the system can be transferred likewise to the other claimed subject matter, and vice versa.

An exemplary embodiment of the system may comprise additionally an overall cooling unit, which is configured to cool components of the magnetic resonance device and/or of the gradient coil unit, wherein the cooling unit is part of the overall cooling unit. During operation of the magnetic resonance device and/or the gradient coil unit, it is typically necessary to cool individual components of the magnetic resonance device and/or of the gradient coil unit in order to control the heating of these components and/or to guarantee their functionality. Customarily, each magnetic resonance device requires and/or may comprise an overall cooling unit, wherein a unit configured to actively lower the temperature of the cooling medium of the overall cooling unit is typically located outside the RF-shielded room and a connection through the RF shield is necessary. This embodiment provides that the cooling line of the overall cooling unit is used to cool the filter. An amount of heat generated by the filter during operation of the gradient coil unit equals less than 1% of the amount of heat generated by the gradient coil unit. In the case of combined usage of the cooling line of the overall cooling unit also for the filter, it is possible to dispense with a separate cooling circuit for the cooling unit for the filter, and therefore such a system can be realized at particularly low cost. The filter unit can comprise the overall cooling unit.

An exemplary embodiment of the system provides that the cooling unit is part of a supply line and/or return line of the overall cooling unit between a cooling reservoir and the magnetic resonance device and/or the gradient coil unit. The flow of the cooling medium typically takes place from the cooling reservoir via the supply line to the gradient coil unit and back to the cooling reservoir via the return line. The cooling reservoir can comprise a unit configured to actively lower the temperature of the cooling medium. The cooling line of the filter unit can correspond to the supply line and/or return line. This embodiment allows a particularly compact construction of the filter unit.

An exemplary embodiment of the system provides that the supply line and/or return line of the overall cooling unit has, at least in segments, a main line and a secondary line parallel thereto, and the cooling line and/or cooling unit is part of the secondary line. The cooling medium flowing through the main line typically differs from the cooling medium flowing through the secondary line in terms of flow velocity and/or pressure and/or volume. The secondary line typically has a smaller diameter than the main line. The main line typically has a higher compressive strength than the secondary line. The main line guarantees unimpeded through-flow of a large quantity of the cooling medium and hence efficient cooling of the magnetic resonance device and/or the gradient coil unit. This embodiment ensures that a partial quantity of the cooling medium used in the overall cooling unit is used and/or channeled off for cooling the filter.

An exemplary embodiment of the system provides that the main line is spaced apart from the filter and/or from the filter unit and/or from the cable unit. According to this embodiment, the filter unit may comprise the secondary line as the cooling line, wherein the main line may be at a distance of at least 20 cm from the filter. This embodiment allows a flexible arrangement of the filter unit.

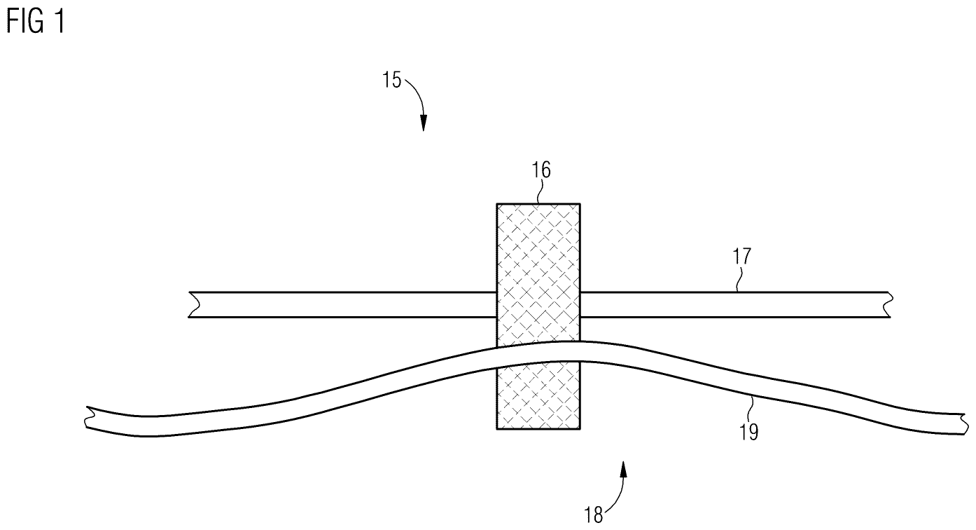

FIG. 1 shows a schematic representation of an exemplary embodiment of a filter unit 15 according to the disclosure. The filter unit (filter) 15 is configured to filter the cable unit (cable assembly, cable) 17 and may comprise one or more filters (filter elements/components) 16 and a cooling unit 18. The cable unit 17 connects a gradient coil unit 14 to a gradient controller 28. The cooling unit 18 may comprise a cooling line 19, through which a cooling medium can flow, and the cooling unit (cooler) 18 is configured to cool the filter 16. According to the first embodiment, the cooling unit 18 is free of air-cooling and/or free of a fan.

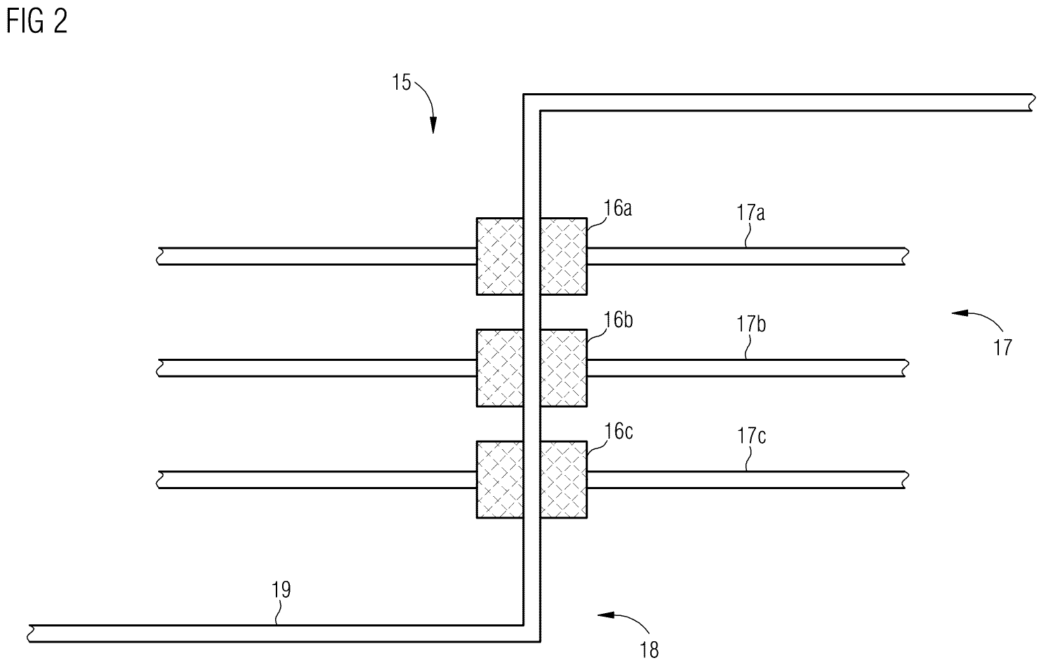

FIG. 2 shows a schematic representation of an exemplary embodiment of a filter unit 15 according to the disclosure. The cable unit 17 to be filtered may comprise, according to the second embodiment, three cable elements 17a, 17b, 17c, and the filter unit 15 may comprise accordingly three filters 16a, 16b, 16c, wherein each filter of the three filters 16a, 16b, 16c is assigned to one cable element of the three cable elements 17a, 17b, 17c. The cooling line 19 is designed such that the three filters 16a, 16b, 16c are cooled in series.

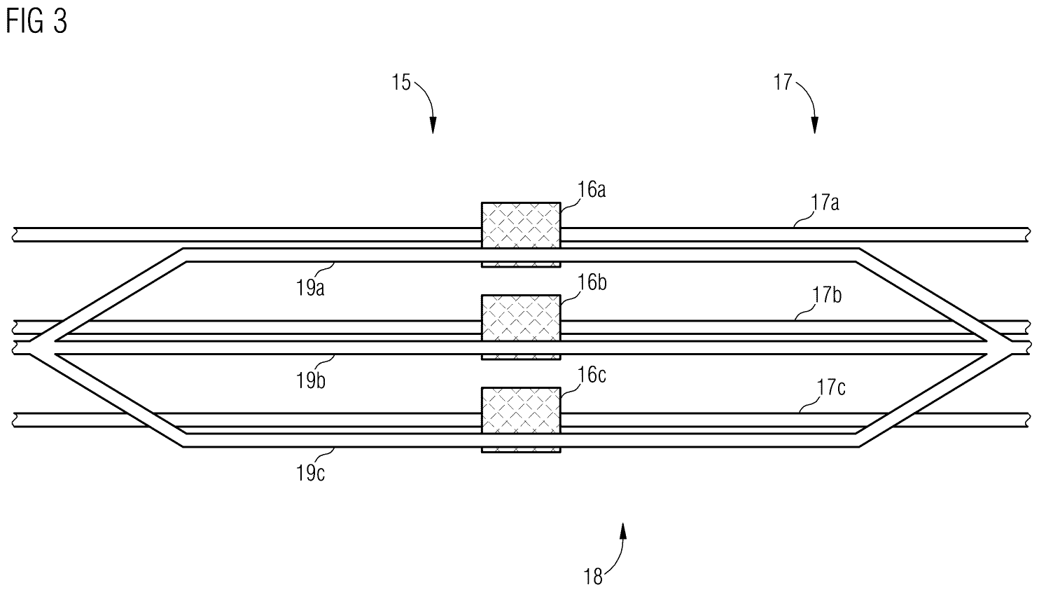

FIG. 3 shows a schematic representation of an exemplary embodiment of a filter unit 15 according to the disclosure. According to the third embodiment, the cooling line 19 may comprise three sub-cooling lines 19a, 19b, 19c, which are parallel to each other. The cable unit 17 to be filtered may comprise, according to the second embodiment, three cable elements 17a, 17b, 17c. The filter unit 15 may comprise three filters 16a, 16b, 16c, wherein each filter of the three filters 16a, 16b, 16c is assigned to one cable element of the three cable elements 17a, 17b, 17c. The three sub-cooling lines 19a, 19b, 19c are configured such that each filter of the at least three filters 16a, 16b, 16c is assigned one sub-cooling line of the three sub-cooling lines 19a, 19b, 19c and/or each filter of the at least three filters 16a, 16b, 16c is cooled by one sub-cooling line of the three sub-cooling lines 19a, 19b, 19c.

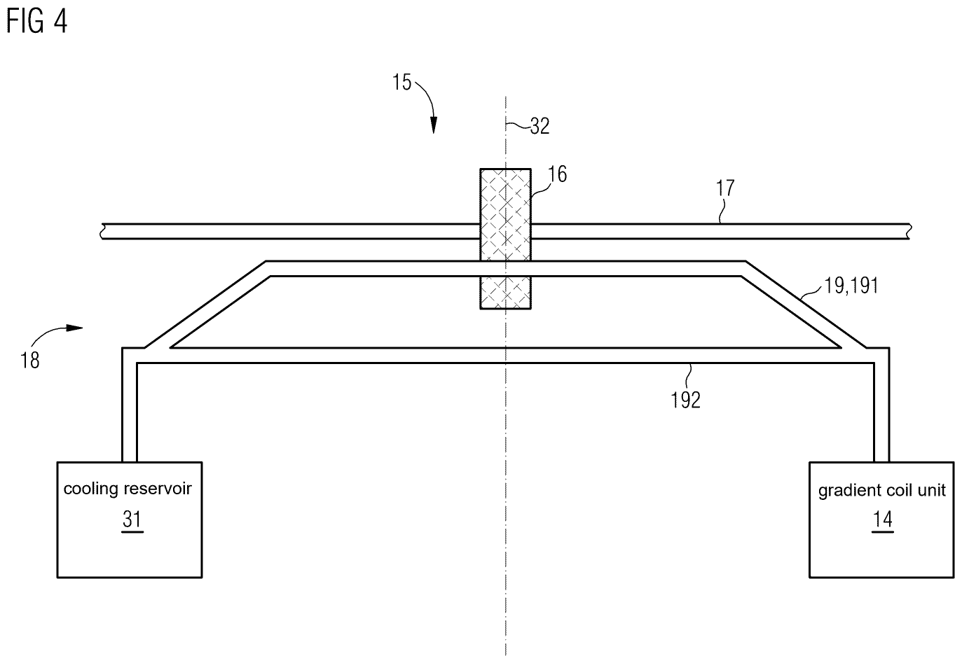

FIG. 4 shows a schematic representation of an exemplary embodiment of a filter unit 15 according to the disclosure. In this case, the cooling unit 18 is part of an overall cooling unit, which is configured to cool components of a magnetic resonance device 11 and/or of the gradient coil unit 14. The cooling unit 18 is part of a supply line between a cooling reservoir 31 and the magnetic resonance device 11 and/or the gradient coil unit 14. The overall cooling unit typically may comprise a return line (not presented here in greater detail), through which the cooling medium can be conducted away after cooling the magnetic resonance device 11 and/or the gradient coil unit 14. The supply line and return line may be part of a cooling circuit which may comprise a unit for active cooling of the cooling medium. The cooling reservoir 31 is typically also part of this cooling circuit. The supply line of the overall cooling unit is divided, at least in segments, into a main line 192 and a secondary line 191 parallel thereto, wherein the cooling line 19 is part of the secondary line 191. The main line 192 is spaced apart from the filter.

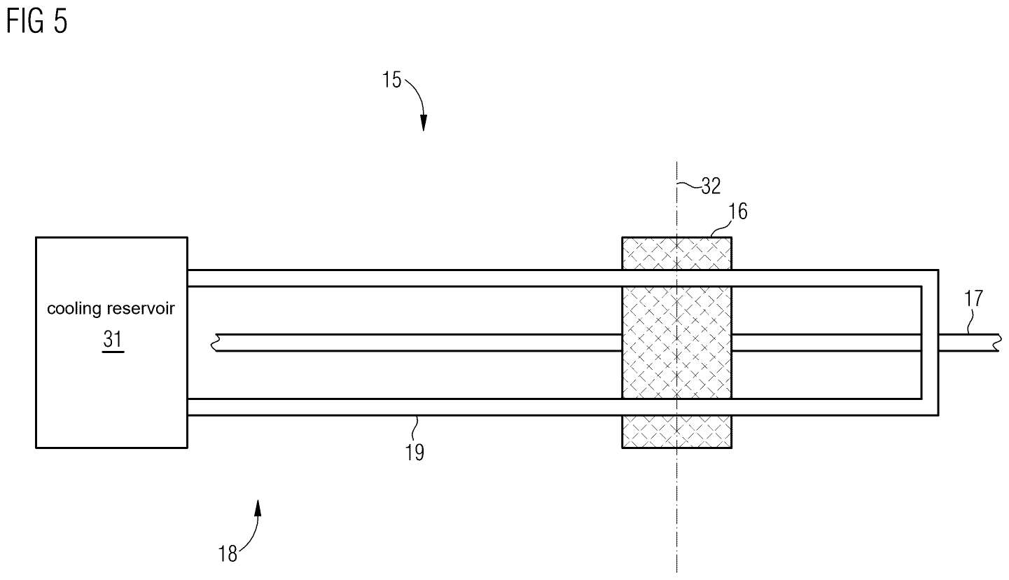

FIG. 5 shows a schematic representation of an exemplary embodiment of a filter unit 15 according to the disclosure. This fifth embodiment provides that the cooling unit 19 is part of a filter cooling circuit and is independent of an overall cooling unit for cooling of components of a magnetic resonance device 11 and/or of the gradient coil unit 14. According to this embodiment, the cooling unit 18 is separate from an overall cooling unit for cooling of components of a magnetic resonance device 11 and/or of the gradient coil unit 14.

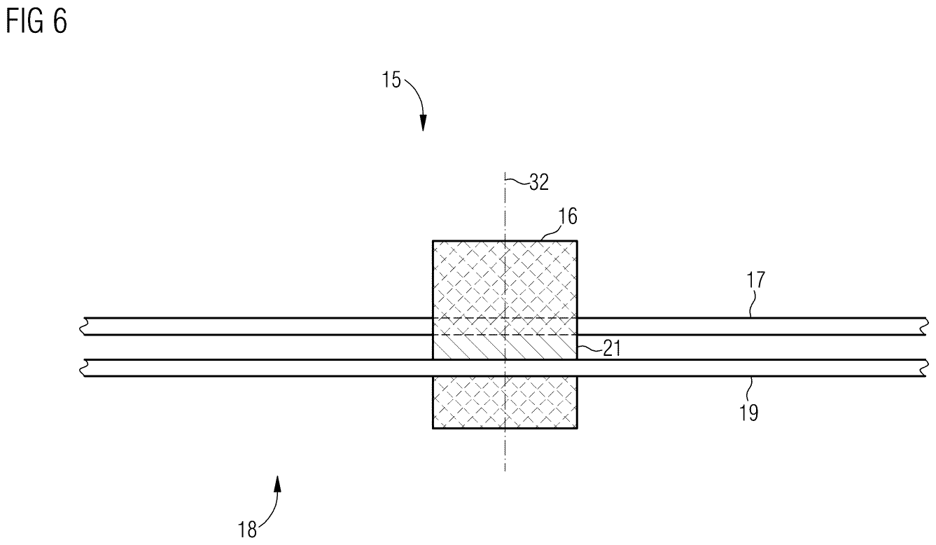

FIG. 6 shows a schematic representation of an exemplary embodiment of a filter unit 15 according to the disclosure. This sixth embodiment provides that cooling unit 18 may comprise a cooling element 21, and the cooling medium influences the temperature of the cooling element.

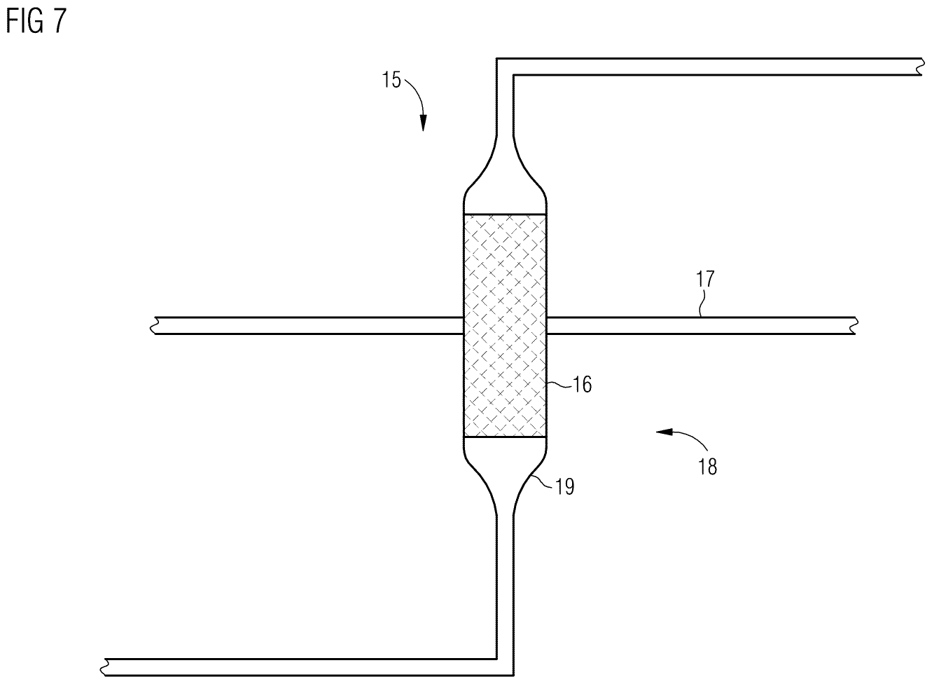

FIG. 7 shows a schematic representation of an exemplary embodiment of a filter unit 15 according to the disclosure, according to which, the filter 16 is integrated in the cooling line 19, in the present case in full.

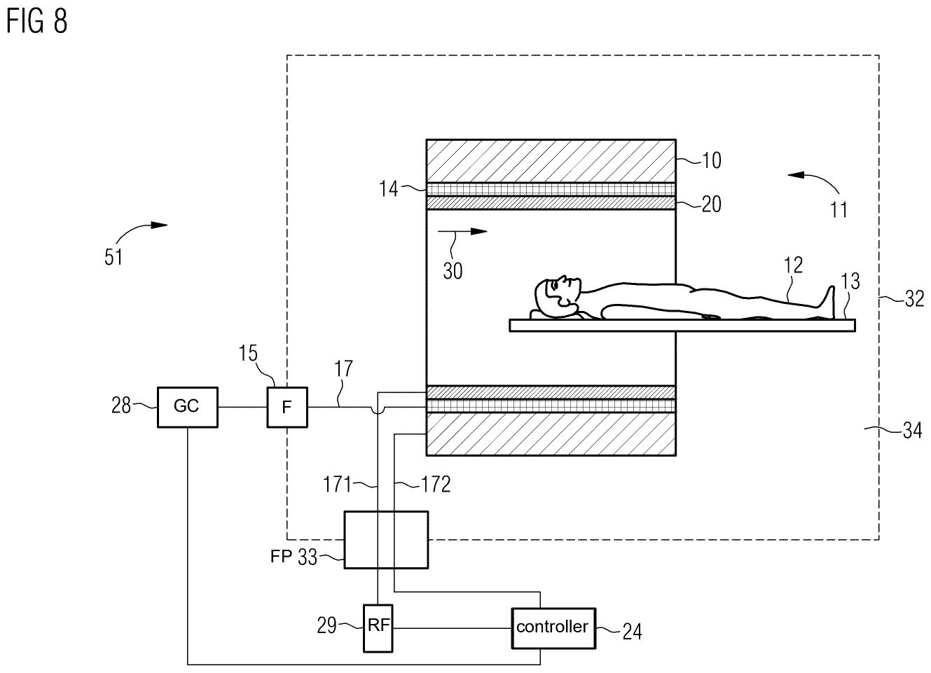

FIG. 8 shows a schematic representation of a system 51 according to the disclosure. The system 51 may comprise a gradient coil unit 14 of a magnetic resonance device 11, a gradient controller 28, an RF-shielded room 34 enclosed by an RF shield 32, and a filter unit 15 for a cable unit 17, which cable unit 17 connects the gradient coil unit 14 to the gradient controller 28. The gradient coil unit 14 is used for spatial encoding during imaging. The gradient coil unit 14 is controlled by means of the gradient controller 28. The gradient controller 28 typically may comprise for this purpose a power amplifier, which is used to generate and/or amplify and/or determine the electrical currents required for the magnetic resonance imaging. The gradient coil unit 14 is located inside the RF-shielded room 34, which RF-shielded room 34 is closed off by the RF shield 32. The gradient controller 28 is located outside the RF-shielded room 34. The filter unit 15 for the cable unit 17 is integrated in the RF shield 32. The RF shield 32 is designed in particular to shield the RF-shielded room 34 from RF fields. The filter unit 15 is configured to maintain an RF-shielding action also at the position at which the cable unit 17 passes through the RF shield 32. The magnetic resonance device 11 may comprise the gradient coil unit 14 and the gradient controller 28 and is hence located in part inside the RF-shielded room 34. The filter unit 15 can comprise a housing unit (not presented here in greater detail), which encloses at least part of the filter, and externally has a maximum temperature of 55° C. during operation of the filter unit 15 and/or of the gradient coil unit 14.

The magnetic resonance device 11 may comprise a main magnet 10 for generating a powerful and constant main magnetic field 30. In addition, the magnetic resonance device 11 may comprise a radiofrequency antenna unit 20, which in the case shown is a body coil that is permanently integrated in the magnetic resonance device 11, and a radiofrequency antenna controller 29 for exciting a polarization, which establishes itself in the main magnetic field 30 generated by the main magnet 10. The radiofrequency antenna unit 20 is controlled by the radiofrequency antenna controller 29 and emits high-frequency radiofrequency pulses. The radiofrequency antenna unit 20 is connected to the radiofrequency antenna controller 29 by a first electrical conductor 171.

The magnetic resonance device 11 may comprise a controller 24 configured to control the main magnet 10, the gradient controller 28, and/or the radiofrequency antenna controller 29. The controller 24 may be configured to centrally control the magnetic resonance device 11, such as the implementation of MR control sequences. The part of the magnetic resonance device 11 located inside the RF shield 32 is connected to the controller 24 by a second electrical conductor 172. In an exemplary embodiment, the controller 24 may include processing circuitry that is configured to perform one or more functions and/or operations of the controller 24. Additionally, or alternatively, one or more components of the controller 24 may include processing circuitry that is configured to perform one or more receptive functions and/or operations of the component(s).

The controller 24 and the radiofrequency (RF) antenna controller 29 are located outside the RF-shielded room 34, whereas the radio frequency (RF) antenna unit 20 and the main magnet 10 are located inside the RF-shielded room 34. The first electrical conductor 171 and the second electrical conductor 172 pass through the RF shield 32 at a position at which the RF shield 32 has a filter plate 33. The filter plate 33 is configured to maintain an RF-shielding action also at this position. The filter plate 33 is integrated in the RF shield 32. The filter unit 15 can also be integrated in the filter plate 33.

In addition, the magnetic resonance device 11 may comprise a cylindrical patient placement region for accommodating a patient 12. The patient 12 can be moved into the patient placement region by means of a patient positioning apparatus 13 of the magnetic resonance device 11. The controller 24 can comprise the gradient controller 28 and/or radiofrequency antenna controller 29. The magnetic resonance device 11 shown can obviously comprise further components that are typically present in magnetic resonance devices 11. Furthermore, since a person skilled in the art knows how a magnetic resonance device 11 works in general, a detailed description of the further components is not given.

Although the disclosure has been illustrated and described in detail using the exemplary embodiments, the disclosure is not limited by the disclosed examples, and a person skilled in the art can derive other variations therefrom without departing from the scope of protection of the disclosure.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A filter unit for a cable unit connecting a gradient coil unit to a gradient controller comprising:
a filter; and
a cooler configured to cool the filter and comprising a cooling line through which a cooling medium can flow.

2. The filter unit as claimed in claim 1, wherein the cable unit comprises at least three cable elements, and the filter unit comprises at least three filters, each filter of the at least three filters being assigned to a respective one of the at least three cable elements, wherein the cooling line is configured such that at least two filters of the at least three filters are cooled in series.

3. The filter unit as claimed in claim 1, wherein at least part of the cooling line comprises at least two sub-cooling lines that are parallel to each other.

4. The filter unit as claimed in claim 3, wherein the cable unit comprises at least three cable elements, and the filter unit comprises at least three filters, each filter of the at least three filters being assigned to a respective one of the at least three cable elements, wherein the at least two sub-cooling lines are configured such that at least two filters of the at least three filters are each assigned a sub-cooling line and/or are each cooled by a sub-cooling line.

5. The filter unit as claimed in claim 1, wherein the cooler is independent of an overall cooling unit configured to cool one or more components of a magnetic resonance device and/or of the gradient coil unit.

6. The filter unit as claimed in claim 1, wherein the cooler comprises a cooling element, and the cooling medium influences the temperature of the cooling element.

7. The filter unit as claimed in claim 1, wherein the filter is integrated in the cooling line.

8. The filter unit as claimed in claim 1, wherein the cooler is free of air-cooling and/or free of a fan.

9. The filter unit as claimed claim 1, wherein the filter unit comprises a housing, wherein the filter unit is configured to cool an exterior of the housing to have a maximum temperature of 55° C. during operation of the filter unit.

10. A system comprising:
an RF-shielded room enclosed by an RF shield;
a gradient coil unit of a magnetic resonance device located inside the RF-shielded room;
a gradient controller located outside the RF-shielded room and connected to the gradient coil unit by a cable unit; and
a filter unit integrated in the RF shield and comprising a filter and a cooler associated with the cable unit, the cooler being configured to cool the filter and comprising a cooling line through which a cooling medium can flow.

11. The system as claimed in claim 10, further comprising an overall cooling unit configured to cool components of the magnetic resonance device and/or of the gradient coil unit, wherein the cooler is part of the overall cooling unit.

12. The system as claimed in claim 11, wherein the cooler is part of a supply line of the overall cooling unit between a cooling reservoir and the magnetic resonance device and/or the gradient coil unit.

13. The system as claimed in claim 12, wherein the supply line of the overall cooling unit comprises, at least in segments, a main line and a secondary line parallel thereto, the cooling line being part of the secondary line.

14. The system as claimed in claim 13, wherein the main line is spaced apart from the filter.
